(19) United States
(12) Patent Application Publication
(10) Pub. No.: US 2026/0271442 A1
(43) Pub. Date: Sep. 10, 2026

(54) LED FILAMENT ARRANGEMENT COMPRISING LIGHT CONVERTING MATERIAL

(71) Applicant: SIGNIFY HOLDING B.V., EINDHOVEN (NL)

(72) Inventors: TIES VAN BOMMEL, HORST (NL); ERIK PETRUS JOHANNES MALLENS, 's HERTOGENBOSCH (NL); MARTINUS PETRUS JOSEPH PEETERS, WEERT (NL)

(21) Appl. No.: 19/166,513

(22) PCT Filed: Mar. 12, 2024
(86) PCT No.: PCT/EP2024/056554

§ 371 Date: Sep. 18, 2025

(30) Foreign Application Priority Data
Mar. 12, 2023 (EP) 23163046.8

(51) Int. Cl. H10H 20/851; F21K 9/232; F21K 9/66; H10H 20/852; H10H 29/14

(52) U.S. Cl. CPC H10H 20/8513; F21K 9/232; F21K 9/66; H10H 20/852; H10H 29/14

(57) ABSTRACT

A LED filament 100 comprising alight transmissive carrier (110) comprising a first surface (112), and a second surface (114) arranged opposite to the first surface. The LED filament further comprises an array of first LEDs (120) arranged on the first surface, wherein the first LEDs are configured to emit blue LED light (125). The LED filament further comprises a first elongated encapsulant (130) covering the first surface and the array of first LEDs, comprising a first luminescent material (132) configured to at least partly convert the emitted blue LED light into first converted light (135), wherein the first luminescent material comprises a green-yellow phosphor. The LED filament further comprises a second elongated encapsulant (140) covering the second surface, comprising a second luminescent material (142) configured to at least partly convert the emitted blue LED light into fourth converted light (145) comprising red light.

### FIELD OF THE INVENTION

The present invention generally relates to the field of light-emitting diode, LED, filaments. More specifically, the present invention relates to a LED filament comprising light converting material.

### BACKGROUND OF THE INVENTION

The use of light emitting diodes (LEDs) for illumination purposes continues to attract attention. Compared to incandescent lamps, fluorescent lamps, neon tube lamps, etc., LEDs provide numerous advantages such as a longer operational life, a reduced power consumption, and an increased efficiency related to the ratio between light energy and heat energy. In particular, LED lamps are highly appreciated as they may be very decorative and versatile in appearance.

US2020/303355A1 discloses a LED-filament that includes a partially light-transmissive substrate and blue LED chips mounted on a front face of the substrate. A first broad-band green to red photoluminescent material and a first narrow-band manganese-activated fluoride red photoluminescent material are covering the blue LED chips and the front face of the substrate. A second broad-band green to red photoluminescent material is covering the back face of the substrate. The LED-filament further includes a second narrow-band manganese-activated fluoride red photoluminescent material on the back face of the substrate in an amount that is less than 5 wt. % of a total red photoluminescent material content on the back face of the substrate.

US2022/107060A1 discloses a LED-filament comprising a partially light transmissive substrate and a plurality of LED chips on a front face of the substrate. A photoluminescent material is in direct contact with and covers all of the plurality of LED chips, and a light scattering layer is in direct contact with and covers the photoluminescence material. The light scattering layer comprises particles of light scattering material. The photoluminescent material comprises a broadband green to red photoluminescence material and narrowband red photoluminescent material. It is of interest to combine the advantageous properties of LEDs according to the above with the advantageous properties of filament lamps. Filament lamps present an aesthetic design as well as a wide light distribution angle. It will be appreciated that combining filament lamps with the properties of LEDs has become a trend due to the high efficiency of LEDs whilst achieving the resemblance to a traditional incandescent light bulb with a visible filament.

In addition to the above-mentioned combination of features of LEDs and traditional incandescent light bulbs, it will be appreciated that it may be desirable to emit light from such an arrangement in an efficient manner whilst at the same time fulfilling certain lighting requirement. For example, including a photoluminescence conversion layer in LEDs may accomplish these objectives. The photoluminescence layer is generally an inorganic phosphor material which converts (a part of) emitted blue LED light into another wavelength, wherein the combination of emitted light is perceived as white light for the human eye.

Hence, it is of interest to provide a lighting filament arrangement or system, provided with LEDs, which can provide homogeneous and efficient lighting.

### SUMMARY OF THE INVENTION

It is an object of the present invention to provide a lighting filament which can present the traditional appearance of light bulbs combined with the efficiency of LEDs, whilst at the same time providing homogeneous lighting in an efficient manner.

This and other objects are achieved by a LED filament having the features in the independent claim. Preferred embodiments are defined in the dependent claims.

Hence, according to the present invention, there is provided a light emitting diode, LED, filament configured to emit LED filament light comprising a light transmissive carrier comprising a first major surface, and a second major surface arranged opposite to the first major surface. The LED filament further comprises an array of a plurality of first LEDs arranged on the first major surface, wherein the plurality of first LEDs is configured to emit blue LED light having a peak emission wavelength within a wavelength range of 430-490 nm. The LED filament further comprises a first elongated encapsulant at least partially covering the first major surface and at least partially enclosing the array of the plurality of first LEDs. The first encapsulant comprises a first luminescent material configured to at least partly convert the emitted blue LED light into first converted light, wherein the first luminescent material comprises a green-yellow phosphor configured to at least partly convert the emitted blue LED light into second converted light comprising green-yellow light having a peak emission wavelength within a wavelength range of 500-600 nm. The first converted light comprises the second converted light. The LED filament further comprises a second elongated encapsulant at least partially covering the second major surface, comprising a second luminescent material configured to at least partly convert the emitted blue LED light into fourth converted light, wherein at least 95 weight percent (w/w %) of the second luminescent material is M′_{z}M_{2-2z}AX₆ doped with tetravalent manganese. M′ comprises an alkaline earth cation, M comprises a cation, and z is in the range from 0 to 1, A comprises a tetravalent cation, and X comprises at least one monovalent anion, the at least one monovalent anion comprising fluorine. The second luminescent material is configured to at least partly convert the emitted blue LED light into fourth converted light comprising red light having a peak emission wavelength within a wavelength range of 600-650 nm.

Thus, the present invention is based on the concept or idea of providing a LED filament which can provide energy efficient light with a homogeneous luminous flux. This is achieved by having the first (elongated) encapsulant comprising the first luminescent material cover the first major surface of the light transmissive carrier, and the second (elongated) encapsulant comprising the second luminescent material cover the second major surface of the light transmissive carrier. Thus, the present invention provides a LED filament which may emit (converted) LED light from both the first major surface and the second major surface of the light transmissive carrier, resulting in an energy efficient and homogeneous emission of LED light.

It will be appreciated that the LED filament comprises a light transmissive carrier, with an array of a plurality of first LEDs arranged on a first major surface of the light transmissive carrier. The light transmissive property of the carrier allows for the emitted blue LED light to be emitted in additional directions such as in the direction of a second major surface of the light transmissive carrier. Hence, the LED filament may result in a more energy efficient and homogenous light source. Additionally, the LED filament may provide an indirect lighting experience. This entails the LED filament arrangement to be adaptable to different lighting needs and/or desires.

It should be noted that the LED filament comprises a first luminescent material covering the first major surface of the light transmissive carrier, comprising a green-yellow phosphor, and a second luminescent material covering the second major surface of the light transmissive carrier, wherein at least 95 weight percent of the second luminescent material is M′_{z}M_{2-2z}AX₆ doped with tetravalent manganese. More specifically, M′ comprises an alkaline earth cation, M comprises a cation, and z is in the range from 0 to 1, A comprises a tetravalent cation, and X comprises at least one monovalent anion, the at least one monovalent anion comprising fluorine. This increases the energy efficiency of the LED filament. Additionally, the present invention is advantageous in that the emitted LED filament light entails a pleasant light experience for users.

In an embodiment, the second luminescent material only comprises M′_{z}M_{2-2z}AX₆ doped with tetravalent manganese, wherein M′ comprises an alkaline earth cation, M comprises a cation, and z is in the range from 0 to 1, A comprises a tetravalent cation, and X comprises at least one monovalent anion, the at least one monovalent anion comprising fluorine; i.e. no other luminescent material configured to generate red light having a peak emission wavelength within a wavelength range of 600-650 nm is present in the second elongated encapsulant.

In an embodiment, the second elongated encapsulant does not comprise any other luminescent material configured to generate light having a peak emission wavelength outside the wavelength range of 600-650 nm.

According to the present invention, there is provided a light transmissive carrier. By the term “carrier”, it is here meant an (elongated) element, body, structure, or the like, suitable or configured to have LEDs arranged thereon. By the term “light transmissive carrier”, it is here meant a carrier which is transparent and/or translucent. The LED filament further comprises a first and second (elongated) encapsulant. By “encapsulant”, it is here meant a material, element, arrangement, or the like, which is configured or arranged to at least partially cover, surround, encapsulate, and/or enclose the first major surface with the array of plurality of first LEDs, and the second major surface, respectively. Furthermore, the first and second encapsulant comprises a first and a second luminescent material, respectively. By “luminescent material”, it is here meant a material, composition, and/or substance which is luminescent and configured to affect light in such a manner that at least some light can pass through the luminescent material. Furthermore, 95 weight percent of the second encapsulant is M′_{z}M_{2-2z}AX₆ doped with tetravalent manganese and configured to at least partly convert the emitted blue LED light into fourth converted light comprising red light. The M′_{z}M_{2-2z}AX₆ doped with tetravalent may also be referred to as a narrow-band manganese-activated fluoride red photoluminescence material.

According to an embodiment of the present invention, the first luminescent material may further comprise a red phosphor configured to at least partly convert at least one of the emitted blue LED light and the second converted light into third converted light comprising red light having a peak emission wavelength within a wavelength range of 600-670 nm. The first converted light comprises the second converted light and the third converted light. Thus, the red phosphor may convert all, or only some, of the emitted blue light and/or the second converted light into third converted light. The present embodiment is advantageous in that the first luminescent material further comprises a red phosphor. This is favorable as it provides a more versatile LED filament regarding different lighting needs and/or desires, e.g. providing light within a specific wavelength range and/or with a specific correlated color temperature, CCT.

According to an embodiment of the present invention, the red phosphor may comprise M′_{z}M_{2-2z}AX₆ doped with tetravalent manganese, wherein M′ may comprise an alkaline earth cation, M may comprise a cation and z is in the range from 0 to 1, A may comprise a tetravalent cation, and X may comprise at least one monovalent anion, the at least one monovalent anion may comprise fluorine. The red phosphor may be configured to at least partly convert at least one of the emitted blue LED light and the second converted light into third converted light comprising red light having a peak emission wavelength within a wavelength range of 600-650 nm. Thus, the red phosphor may convert all, or only some, of the emitted blue LED light and/or the second converted light into third converted light. The present embodiment is advantageous in that the red phosphor is a narrow-band manganese-activated fluoride red photoluminescence material. This may increase the energy efficiency of the LED filament.

Herein, M′ₓM₂₋₂ₓAX₆ doped with tetravalent manganese, may further also shortly be indicated as “phosphor”, i.e. the phrase “phosphor comprising M′ₓM₂₋₂ₓAX₆ doped with tetravalent manganese” may in an embodiment also be read as M′ₓM₂₋₂ₓAX₆ doped with tetravalent manganese phosphor, or (tetravalent) Mn-doped M′ₓM₂₋₂ₓAX₆ phosphor, or shortly “phosphor”.

Relevant alkaline cations (M) are sodium (Na), potassium (K) and rubidium (Rb). Optionally, also lithium (Li) and/or cesium (Cs) may be applied. In a preferred embodiment, M comprises at least potassium. In yet another embodiment, M comprises at least rubidium. The phrase “wherein M comprises at least potassium” indicates for instance that of all M cations in a mole M′ₓM₂₋₂ₓAX₆, a fraction comprises K⁺ and an optionally remaining fraction comprises one or more other monovalent (alkaline) cations (see also below). In another preferred embodiment, M comprises at least potassium and rubidium. Optionally, the M′ₓM₂₋₂ₓAX₆ luminescent material has the hexagonal phase. In yet another embodiment, the M′ₓM₂₋₂ₓAX₆ luminescent material has the cubic phase.

Relevant alkaline earth cations (M′) are magnesium (Mg), strontium (Sr), calcium (Ca) and barium (Ba), especially one or more of Sr and Ba.

In an embodiment, a combination of different alkaline cations may be applied. In yet another embodiment, a combination of different alkaline earth cations may be applied. In yet another embodiment, a combination of one or more alkaline cations and one or more alkaline earth cations may be applied. For instance, KRb_{0.5}Sr_{0.25}AX₆ might be applied. As indicated above, x may be in the range of 0-1, especially x<1. In an embodiment, x=0.

The term “tetravalent manganese” refers to Mn⁴⁺. This is a well-known luminescent ion. In the formula as indicated above, part of the tetravalent cation A (such as Si) is being replaced by manganese. Hence, M′ₓM₂₋₂ₓAX₆ doped with tetravalent manganese may also be indicated as M′ₓM₂₋₂ₓA₁₋ₘMnₘX₆. The mole percentage of manganese, i.e. the percentage it replaces the tetravalent cation A will in general be in the range of 0.1-15%, especially 1-12%, i.e. m is in the range of 0.001-0.15, especially in the range of 0.01-0.12.

A comprises a tetravalent cation, and preferably at least comprises silicon. A may optionally (further) comprise one or more of titanium (Ti), germanium (Ge), stannum (Sn) and zinc (Zn). Preferably, at least 80%, even more preferably at least 90%, such as at least 95% of M consists of silicon. Hence, in a specific embodiment, M′ₓM₂₋₂ₓAX₆ may also be described as M′ₓM₂₋₂ₓA_{1-m-t-g-s-Zr}MnₘTiₜGe_{g}SnₛZr_{Zr}X₆, wherein m and x are as indicated above, and wherein t, g, s, zr are each individually preferably in the range of 0-0.2, especially 0-0.1, even more especially 0-0.05, wherein t+g+s+zr is smaller than 1, especially equal to or smaller than 0.2, preferably in the range of 0-0.2, especially 0-0.1, even more especially 0-0.05, and wherein A is especially Si. X is preferably fluorine (F).

As indicated above, M relates to monovalent cations, but preferably at least comprises potassium and/or rubidium. Other monovalent cations that may further be comprised by M can be selected from the group consisting of lithium (Li), sodium (Na), cesium (Cs) and ammonium (NH₄⁺). In an embodiment, preferably at least 80% (i.e. 80% of all moles of the type M), even more preferably at least 90%, such as 95% of M consists of potassium and/or rubidium. Especially, in these embodiments x is thus zero.

Hence, in a specific embodiment, M′ₓM₂₋₂ₓAX₆ can also be described as (K_{l-r-l-n-c-nh} RbᵣLiₗNaₙCs_{c}(NH₄)ₙₕ)₂AX₆, wherein r is in the range of 0-1, wherein l, n, c, nh are each individually preferably in the range of 0-1, preferably 0-0.2, especially 0-0.1, even more especially 0-0.05, and wherein r+1+n+c+nh is in the range of 0-1, especially 1+n+c+nh is smaller than 1, especially equal to or smaller than 0.2, preferably in the range of 0-0.2, especially 0-0.1, even more especially 0-0.05. X is preferably fluorine (F).

As indicated above, instead of or in addition to the alkaline cation(s), also one or more alkaline earth cations may be present. Hence, in a specific embodiment, M′ₓM₂₋₂ₓAX₆ can also be described as Mg_{mg}Ca_{ca}SrₛᵣBa_{ba}(KₖRbᵣLiₗNaₙCs_{c}(NH₄)ₙₕ)₂AX₆, with k, r, l, n, c, nh each individually being in the range of 0-1, wherein mg, ca, sr, ba are each individually in the range of 0-1, and wherein mg+ca+sr+ba+k+r+l+n+c+nh=1. In embodiments, k=1, and the others (mg, ca, sr, ba, r, l, n, c, nh) are zero.

As indicated above, X relates to a monovalent anion, but at least comprises fluorine. Other monovalent anions that may optionally be present may be selected from the group consisting of chlorine (Cl), bromine (Br), and iodine (I). Preferably, at least 80%, even more preferably at least 90%, such as 95% of X consists of fluorine. Hence, in a specific embodiment, M′ₓM₂₋₂ₓAX₆ can also be described as M′ₓM₂₋₂ₓA(F_{1-cl-b-i}Cl_{cl}Br_{b}Iᵢ)₆, wherein cl, b, i are each individually preferably in the range of 0-0.2, especially 0-0.1, even more especially 0-0.05, and wherein cl+b+i is smaller than 1, especially equal to or smaller than 0.2, preferably in the range of 0-0.2, especially 0-0.1, even more especially 0-0.05. Especially, X essentially consists of F (fluorine).

Hence, M′_{X}M_{2-2X}AX₆ can also be described as (K_{l-r-l-n-c-nh}RbᵣLiₗNaₙCs_{c}(NH₄)ₙₕ)₂Si_{l-m-t-g-s-zr}MnₘTiₜGe_{g}SnₛZr_{Zr}(F_{1-cl-b-i}Cl_{cl}Br_{b}Iᵢ)₆, with the values for r, l, n, c, nh, m, t, g, s, zr, cl, b, i as indicated above. X is preferably fluorine (F).

Even more especially, M′ₓM_{2-2X}AX₆ can also be described as Mg_{mg}Ca_{ca}SrₛᵣBa_{ba}(KₖRbᵣLiₗNaₙCs_{c}(NH₄)ₙₕ)₂Si_{l-m-t-g-s-zr}MnₘTiₜGe_{g}SnₛZr_{Zr}(F_{1-cl-b-i}Cl_{cl}Br_{b}Iᵢ)₆, with k, r, l, n, c, nh each individually being in the range of 0-1, wherein mg, ca, sr, ba are each individually in the range of 0-1, wherein mg+ca+sr+ba+k+r+l+n+c+nh=1, and with the values for m, t, g, s, zr, cl, b, i as indicated above. X is preferably fluorine (F).

In an embodiment, M′ₓM_{2-2X}AX₆ comprises K₂SiF₆ (indicated herein also as KSiF system). As indicated above, in another preferred embodiment, M′ₓM₂₋₂ₓAX₆ comprises KRbSiF₆ (i.e. r=0.5 and l, n, c, nh, t, g, s, zr, cl, b, i are 0) (herein also indicated as K, Rb system). As indicated above, part of silicon is replaced by manganese (i.e. the formula may also be described as K₂Si₁₋ₘMnₘF₆ or KR_{b}Si₁₋ₘMnₘF₆, with m as indicated above, or as KRbSiF₆:Mn and K₂SiF₆:Mn, respectively). As manganese replaces part of a host lattice ion and has a specific function, it is also indicated as “dopant” or “activator”. Hence, the hexafluorosilicate is doped or activated with manganese (Mn⁴⁺).

In specific embodiments, the luminescent material may comprise (K, Rb)₂SiF₆:Mn⁴⁺. Alternatively or additionally, in embodiments the third luminescent material may comprise K₂SiF₆:Mn⁴⁺. Alternatively or additionally, in embodiments the third luminescent material may comprise K₂TiF₆:Mn⁴⁺. In embodiments, the third luminescent material may comprise K₂(Si,Ti)F₆:Mn⁴⁺. As can be derived from the above, “Si,Ti” may indicate one or more of Si and Ti.

According to an embodiment of the present invention, the first luminescent material may further comprise a red nitride phosphor configured to at least partly convert at least one of the emitted blue LED light and the first converted light into fifth converted light comprising red light having an emission peak wavelength within a wavelength range of 640-680 nm. Preferably, the nitride phosphor may comprise at least one of M₂Si₅N₈:Eu2+, MAlSiN₃:Eu2+, and M₂AlSi₃O₂N₅:Eu2+, wherein M may comprise one or more of Ba, Sr, and Ca. Hence, the red nitride phosphor may convert all of the emitted blue LED light and/or the first converted light, or only some. The present embodiment is advantageous in that the first luminescent material may comprise a red nitride phosphor. This entails the LED filament arrangement to be adaptable to different lighting needs and/or desires regarding e.g. a specific correlated color temperature, CCT. According to an example, the second luminescent material further comprises a green-yellow phosphor to at least partly convert the emitted blue LED light into sixth converted light comprising green-yellow light having a peak emission wavelength within a wavelength range of 500-600 nm. This example is advantageous in that the emitted light from the first major surface and the second major surface may have the same CCT. This may entail a pleasant light experience for users of the LED filament.

According to an embodiment of the present invention, at least 95 weight 20 percent (w/w %) of the second luminescent material may be K₂SiF₆:Mn⁴⁺. Thus, 95 weight percent or more of the second luminescent material may be K₂SiF₆:Mn⁴⁺. The present embodiment is advantageous in that the use of K₂SiF₆:Mn⁴⁺ as 95 or more weight percent of the second luminescent material may result in an increased energy efficiency of the LED filament.

According to an embodiment of the present invention, the green-yellow phosphor may be A₃B₅O₁₂:Ce³⁺, wherein A may comprise at least one of Y, La, Gd, Tb and Lu, and B may comprise at least one of Al, Ga, In and Sc. Hence, the green-yellow phosphor may be A₃B₅Oi₂:Ce³⁺, wherein A may comprise a combination of Y, La, Gd, Tb, and Lu, or the mentioned elements on their own. Furthermore, B may comprise a combination of Al, Ga, In, and Sc, or the mentioned elements on their own. The present embodiment is advantageous in that the aforementioned possible combinations of elements regarding the green-yellow phosphor may result in an increased energy efficiency of the LED filament. Furthermore, the emitted LED filament light provides a pleasant light experience for users of the LED filament.

According to an embodiment of the present invention, the LED filament light may have a correlated color temperature in a range from 1500K to 2800K. The present embodiment is advantageous in that the emitted LED filament light entails a pleasant light experience for users of the LED filament.

According to an embodiment of the present invention, the first luminescent material in the first encapsulant may have a first concentration, C₁, and the second luminescent material in the second encapsulant may have a second concentration, C₂, wherein C₁≥1.2·C₂ is fulfilled. Hence, the first concentration, C₁, of the first luminescent material may be at least 20% higher than the second concentration, C₂, of the second luminescent material. The present embodiment is advantageous in that the first concentration, C₁, of the first luminescent material may be the same or higher compared with the second concentration, C₂, of the second luminescent material. This allows the present embodiment to be more versatile regarding different lighting needs and/or desires, e.g. providing light within a specific wavelength range.

According to an embodiment of the present invention, the LED filament may comprise a third encapsulant arranged between the first encapsulant and the first major surface, and at least partially covering the first major surface and at least partially enclosing the array of the plurality of first LEDs. The third encapsulant may comprise a light scattering material configured to at least partly reflect the emitted blue LED light through the light transmissive carrier. Hence, the third encapsulant may be arranged between the first encapsulant and the first major surface to reflect all of the emitted blue LED light, or only some, back through the light transmissive carrier. The present embodiment is advantageous in that the third encapsulant may comprise a light scattering material. This entails the amount of light transmission to the second major surface to increase. The present embodiment may therefore improve the energy efficiency of the LED filament. Additionally, the homogeneity of the emitted LED filament light may be increased. By “light scattering material”, it is here meant a material, composition, and/or substance which may scatter incident light, i.e. affecting incident light in such a manner that the direction of at least some of the scattered incident light deviates from its original direction.

According to an embodiment of the present invention, the light scattering material may be configured to reflect 20% to 80% of the emitted blue LED light in a direction facing away from the second major surface, wherein at least a portion of the reflected emitted blue LED light is transmitted through the light transmissive carrier. Hence, the amount of emitted blue LED light reaching the second major surface, and thus the second luminescent material, is increased. The present embodiment is advantageous in that the amount of light transmission to the second major surface may increase. Therefore, it may follow that the energy efficiency of the LED filament increases. Accordingly, the homogeneity of the emitted LED filament light may increase as well.

According to an embodiment of the present invention, the first encapsulant may comprise a first (average) thickness, T₁, in a direction parallel to a normal, N of the first major surface and the third encapsulant may comprise a third (average) thickness, T₃, in a direction parallel to a normal, N of the first major surface, wherein T₃>T₁. Thus, the third encapsulant may be thicker compared to the first encapsulant. The present embodiment is advantageous in that the first encapsulant is arranged at a greater distance from the array of the plurality of first LEDs. This may result in a further reduced risk of quenching of the first luminescent material comprising the green-yellow phosphor and the red phosphor. Thus may entail a reduced risk of emission loss of the emitted LED filament light. Additionally, the present embodiment is advantageous in that the amount of light transmission to the second major surface may increase. This entails a more energy efficient LED filament.

According to an embodiment of the present invention, the LED filament may comprise a fourth encapsulant arranged between the third encapsulant and the first major surface and at least partially covering the first major surface and at least partially enclosing the array of the plurality of first LEDs, wherein the fourth encapsulant may be transparent. Hence, the fourth (transparent) encapsulant may be arranged between the third encapsulant and the first major surface. The present embodiment is advantageous in that the amount of light transmission to the second major surface may increase. This entails a more energy efficient LED filament.

According to an embodiment of the present invention, the third encapsulant may comprise a third (average) thickness, T₃, in a direction parallel to a normal, N of the first major surface, and the fourth encapsulant may comprise a fourth (average) thickness, T₄, in a direction parallel to a normal, N of the first major surface, wherein T₄>T₃. Thus, the fourth encapsulant may be thicker compared to the third encapsulant. The present embodiment is advantageous in that third encapsulant is arranged at a greater distance from the array of the plurality of first LEDs. This may result in an increase of the amount of light transmission to the second major surface. This increase may result in a more energy efficient LED filament. According to an example, the LED filament may comprise a fifth encapsulant arranged between the second encapsulant and the second major surface and at least partially covering the second major surface, wherein the fifth encapsulant may be light transmissive. Hence, the (light transmissive) fifth encapsulant may be arranged between the second encapsulant and the second major surface. The present example is advantageous in that the fifth encapsulant may entail an increased amount of light transmission to the second major surface. Therefore, the present example may result in a more energy efficient LED filament.

According to an embodiment of the present invention, there is provided a LED filament lamp comprising at least one of the LED filament, a light transmissive envelope at least partially enclosing the LED filament, and a base. The base comprises a cap arranged to mechanically and electrically connect the LED lamp to a socket of a luminaire. By the term “(light transmissive) envelope”, it is here meant a cover, casing or the like configured to affect light in such a manner that at least some light can pass through the envelope. The LED filament lamp further comprises a cap which enables the LED lamp to be mechanically and electrically connected to a socket of a luminaire. By the term “cap”, it is here meant a coupling, connector, or the like, which establish both mechanical and electrical connection between involved elements, components, or the like. The present embodiment is advantageous in that the LED filament lamp comprises an envelope which at least partially encloses the at least one LED filament. This provides a protective barrier, blockade, etc. in regard to physical contact for the at least one LED filament. This is favorably as components such as LED filaments may be sensitive to physical contact. Additionally, the present embodiment of the LED filament arrangement is advantageous in being aesthetically attractive.

According to an embodiment of the present invention, the LED filament comprised of the LED filament lamp may be arranged such that a first distance, D₁, between the first major surface and the envelope, and a second distance, D₂, between the second major surface and the envelope, fulfills D₂<D₁. Hence, the second major surface may be closer to the envelope in relation to the first major surface. According to an example, the first major surface, with the array of the plurality of first LEDs arranged thereon, may face towards a midpoint of the envelope. The second major surface may therefore consequently face outwards from the midpoint of the envelope. The present embodiment is advantageous in that the risk of glare from the emitted LED filament light is reduced. This entails a more pleasant lighting experience for users of the LED filament lamp. Additionally, the present embodiment is advantageous in being further aesthetically attractive.

Further objectives of, features of, and advantages with, the present invention will become apparent when studying the following detailed disclosure, the drawings, and the appended claims. Those skilled in the art will realize that different features of the present invention can be combined to create embodiments other than those described in the following.

### BRIEF DESCRIPTION OF THE DRAWINGS

This and other aspects of the present invention will now be described in more detail, with reference to the appended drawings showing embodiment(s) of the invention.

FIG. 1 is a schematic view of a LED filament according to an exemplifying embodiment of the present invention.

FIGS. 2a and 2b are schematic views of a LED filament according to exemplifying embodiments of the present invention from a top view and a bottom view, respectively.

FIG. 3 is a schematic view of a LED filament according to an exemplifying embodiment of the present invention.

FIG. 4 is a schematic view of a LED filament lamp comprising two LED filaments according to an exemplifying embodiment of the present invention.

FIGS. 5a to 5c are diagrams illustrating emission intensity against corresponding wavelength of a LED filament according to exemplifying embodiments of the present invention.

### DETAILED DESCRIPTION

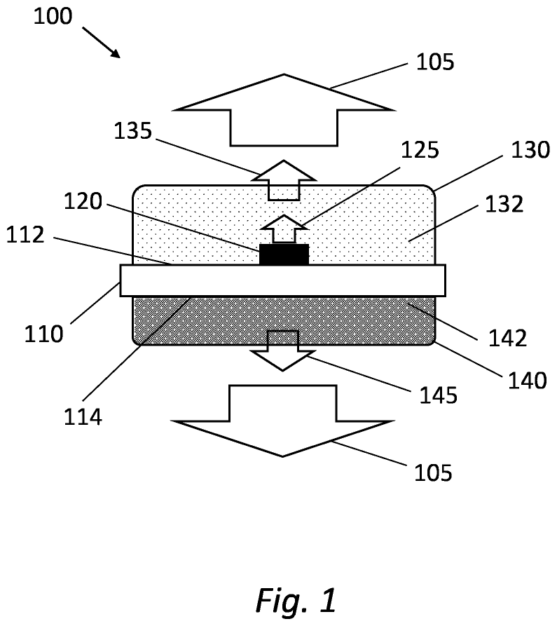

FIG. 1 is a schematic view of a LED filament 100 according to an exemplifying embodiment of the present invention.

The LED filament 100 in FIG. 1 is configured to emit LED filament light 105. The LED filament 100 comprises a light transmissive carrier 110 comprising a first major surface 112 and a second major surface 114 arranged opposite to the first major surface 112. Preferably, the LED filament 100 has a length, L, and a width, W, wherein L>5W. The light transmissive carrier 110 may, for instance, be a substrate, that may be rigid (made from e.g. a polymer, glass, quartz, metal, or sapphire) or flexible (e.g. made of a polymer or metal e.g. a film or foil).

The LED filament 100 further comprises an array of a plurality of first LEDs 120 arranged on the first major surface 112, wherein the plurality of first LEDs 120 is configured to emit blue LED light 125 having a peak emission wavelength within a wavelength range of 430-490 nm. The LED filament 100 furthermore comprises a first elongated encapsulant 130 at least partially covering the first major surface 112 and at least partially enclosing the array of the plurality of first LEDs 120. The first encapsulant 130 comprises a first luminescent material 132 configured to at least partly convert at least one of the emitted blue LED light 125 and the second converted light into first converted light 135. In other words, all of the emitted blue LED light 125 may be converted to first converted light 135, or only some. The first luminescent material 132 comprises a green-yellow phosphor configured to at least partly convert the emitted blue LED light 125 into second converted light comprising green-yellow light having a peak emission wavelength within a wavelength range of 500-600 nm. The emitted light from the first major surface 112 may include at least a part of the first converted light 134 and/or at least a part of the emitted blue LED light 125.

The LED filament 100 further comprises a second elongated encapsulant 140 at least partially covering the second major surface 114. The second encapsulant 140 comprises a second luminescent material 142, wherein at least 95 weight percent (w/w %) of the second luminescent material 142 is M′_{z}M_{2-2z}AX₆ doped with tetravalent manganese. As an example, the weight percent range of the M′_{z}M_{2-2z}AX₆ being present in the second luminescent material 142 may be 75-99w/w %. Furthermore, it is preferable that the weight percent of the M′_{z}M_{2-2z}AX₆ present in the second luminescent material 142 is 95 w/w % or higher. The variables of the chemical formula correspond to M′ comprising an alkaline earth cation, M comprising a cation, and z is in the range from 0 to 1, A comprising a tetravalent cation, and X comprising at least one monovalent anion, the at least one monovalent anion comprising fluorine. Another reference for mentioned chemical formula may be a narrow-band manganese-activated fluoride red photoluminescence material, wherein an example of such photoluminescence material is KSiF phosphor. According to another example, the narrow-band manganese-activated fluoride red photoluminescence material may be K₂SiF₆:Mn⁴¹. The second luminescent material 142 is configured to at least partly convert the emitted blue LED light 125 into fourth converted light 145 comprising red light having a peak emission wavelength within a wavelength range of 600-650 nm. In other words, the fourth converted light 145 may convert all of the emitted blue LED light 125, or only some.

Furthermore, the emitted light from the second major surface 114 may include at least a part of the fourth converted light 145 and/or at least a part of the emitted blue LED light 125. It should be noted that the emitted LED filament light 105 comprises at least one of first converted light 135 and fourth converted light 145. Furthermore, the emitted LED filament light 105 may comprise at least some emitted blue LED light 125 that did not get converted by the first and/or second luminescent material 132, 142.

According to an example, 70% of the emitted blue LED light 125 is provided towards the first elongated encapsulant 130 and 30% of the emitted blue LED light 125 is provided towards the second elongated encapsulant 140. According to the example, the emitted LED filament light 105 may have a CCT above 2800K. According to another example, the emitted LED filament light 105 may have a CCT below 2800K. According to this example, the CCT of the emitted filament light 105 may be below 2500K.

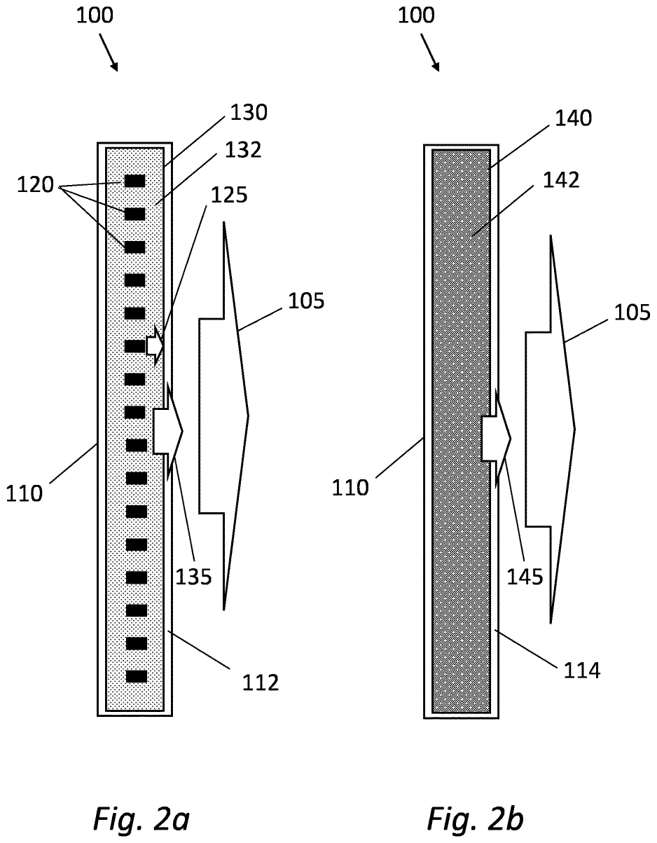

FIGS. 2a and 2b are schematic views of a LED filament 100 according to exemplifying embodiments of the present invention from a top view and a bottom view, respectively. It should be noted that the LED filament 100 shown in FIGS. 2a and 2b have several features in common with the LED filament 100 shown in FIG. 1, and it is hereby referred to FIG. 1 and the associated text for an increased understanding of some of the features and/or functions of the LED filament 100.

FIG. 2a shows a LED filament 100 viewed from a top view. The LED filament 100, configured to emit LED filament light 105, comprises a light transmissive carrier 110 comprising a first major surface 112, and a second major surface 114 arranged opposite to the first major surface 112. The emitted LED filament light 105 of the LED filament 100 may have a CCT in a range from 1500K to 2800K. The LED filament 100 further comprises a first elongated encapsulant 130 at least partially covering the first major surface 112 and at least partially enclosing an array of plurality of first LEDs 120 arranged on the first major surface 112. The first encapsulant 130 comprises a first luminescent material 132 configured to at least partly convert emitted blue LED light 125 emitted from the array of the plurality of first LEDs 120 into first converted light 135. The first luminescent material 132 comprises a green-yellow phosphor configured to at least partly convert the emitted blue LED light 125 into second converted light comprising green-yellow light having a peak emission wavelength within a wavelength range of 500-600 nm. The first luminescent material 132 further comprises a red phosphor configured to at least partly convert the emitted blue LED light 125 into third converted light comprising red light having a peak emission wavelength within a wavelength range of 600-670 nm. Thus, the first converted light 135 may comprise at least a part of the second converted light and/or the third converted light. According to an example, 70% of the emitted blue LED light 125 is provided towards the first elongated encapsulant 130 and 30% of the emitted blue LED light 125 is provided towards the second elongated encapsulant 140. According to the example, the emitted LED filament light 105 may have a CCT below 2800K. According to this example, the CCT of the emitted filament light 105 may also be below 2500K. According to another example, the emitted LED filament light 105 may have a CCT above 2800K.

The red phosphor of the first luminescent material 132 comprises M′_{z}M_{2-2z}AX₆ doped with tetravalent manganese, wherein M′ comprises an alkaline earth cation, M comprises a cation, and z is in the range from 0 to 1, A comprises a tetravalent cation, and X comprises at least one monovalent anion, the at least one monovalent anion comprising fluorine. It should be noted that the chemical formula of the red phosphor of the first luminescent material 132 may be the same or different in relation to the chemical formula of the second luminescent material 142. The red phosphor of the first luminescent material 132 is configured to at least partly convert at least one of the emitted blue LED light 125 and the second converted light into third converted light comprising red light having a peak emission wavelength within a wavelength range of 600-650 nm. The first converted light 135 may comprise at least a part of the second converted light and/or at least a part of the third converted light. Furthermore, the emitted light from the first major surface 112 may include at least a part of the first converted light 135 and/or at least a part of the emitted blue LED light 125.

The first luminescent material 132 further comprises a red nitride phosphor configured to at least partly convert at least one of the emitted blue LED light 125 and the first converted light 135 into fifth converted light comprising red light having an emission peak wavelength within a wavelength range of 640-680 nm. Hence, the red nitride phosphor may convert at least a part of the emitted blue LED light 125 and/or at least a part of the first converted light 135 into fifth converted light. Preferably, the nitride phosphor comprises at least one of M₂Si₅Ns:Eu2+, MAlSiN₃:Eu2+, and M₂AlSi₃O₂N₅:Eu2+, wherein M comprises one or more of Ba, Sr and Ca. It should be noted that the weight percent of the aforementioned element(s) of variable M may be the same or different in relation to each other. The emitted light from the first major surface 112 may include at least a part of the first converted light 134, at least a part of the emitted blue LED light 125, and/or at least a part of the fifth converted light 135.

The green-yellow phosphor of the first luminescent material 132 is A₃B₅O₁₂:Ce³⁺. The variables of the chemical formula correspond to A comprising at least one of Y, La, Gd, Tb and Lu, and B comprising at least one of Al, Ga, In and Sc. It should be noted that the weight percent of the aforementioned element(s) of variables A and B may be the same or different in relation to each other, respectively.

FIG. 2b shows a LED filament 100 viewed from a bottom view. The LED filament 100 further comprises a second elongated encapsulant 140 comprising a second luminescent material 142. At least 95 weight percent (w/w %) of the second luminescent material 142 is K₂SiF₆:Mn⁴⁺. As an example, the weight percent range of the K₂SiF₆:Mn⁴⁺. being present in the second luminescent material 142 may be 75-99w/w %. Furthermore, it is preferable that the weight percent of the K₂SiF₆:Mn⁴⁺ present in the second luminescent material 142 is 95 w/w % or higher.

The first luminescent material 132 in the first encapsulant 130 has a first concentration, C₁, and the second luminescent material 142 in the second encapsulant 140 has a second concentration, C₂, wherein C₁≥1.2·C₂ is fulfilled. Hence, the first concentration, C₁, of the first luminescent material 132 may be at least 20% higher in relation to the second concentration, C₂, of the second luminescent material 142. As an example, the range of the first concentration, C₁, in relation to the second concentration, C₂, may be 20%-40% higher.

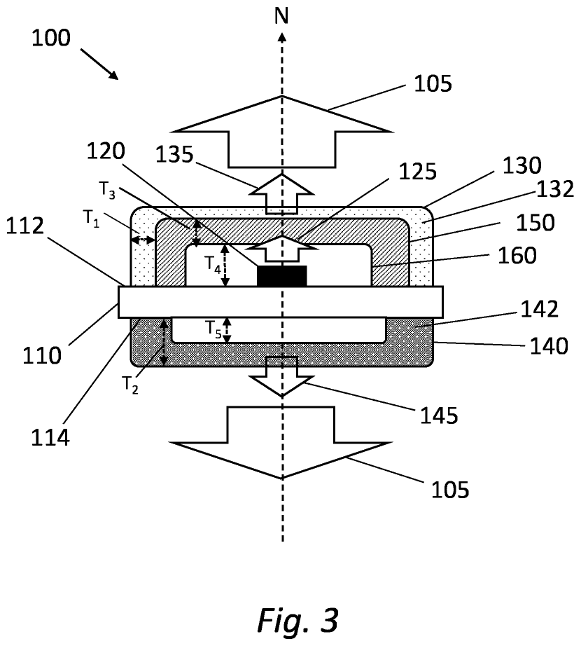

FIG. 3 is a schematic view of a LED filament 100 according to an exemplifying embodiment of the present invention. It should be noted that the LED filament 100 shown in FIG. 3 has several features in common with the LED filament 100 shown in FIG. 1, and it is hereby referred to FIG. 1 and the associated text for an increased understanding of some of the features and/or functions of the LED filament 100.

The LED filament 100 according to FIG. 3 is configured to emit LED filament light 105 and comprises a light transmissive carrier 110 comprising a first major surface 112, and a second major surface 114 arranged opposite to the first major surface 112. The LED filament 100 further comprises a first elongated encapsulant 130 at least partially covering the first major surface 112 and at least partially enclosing an array of plurality of first LEDs 120 arranged on the first major surface 112. The first encapsulant 130 comprises a first luminescent material 132 configured to at least partly convert emitted blue LED light 125 emitted from the array of the plurality of first LEDs 120 into first converted light 135. The LED filament 100 further comprises a second elongated encapsulant 140 comprising a second luminescent material 142.

The LED filament 100 further comprises a third encapsulant 150 arranged between the first encapsulant 130 and the first major surface 112, and at least partially covering the first major surface 112 and at least partially enclosing the array of the plurality of first LEDs 120. The third encapsulant 150 comprises a light scattering material configured to at least partly reflect the emitted blue LED light 125 through the light transmissive carrier 110. Hence, all or only a part of the emitted blue LED light 125 may be reflected through the light transmissive carrier 110 via the light scattering material. Some of the emitted blue LED light 125 that did not get reflected by the light scattering material may be emitted as part of the LED filament light 105. Additionally, some of the emitted blue LED light 125 that did not get reflected by the light scattering material may be converted by the first encapsulant 130 into first converted light 135. The emitted light from the first major surface 112 may have the same or different luminous flux in relation to the luminous flux of the emitted light from the second major surface 114. The light scattering material is configured to reflect 20% to 80% of the emitted blue LED light 125 in a direction facing away from the second major surface 114. By “a direction facing away from the second major surface”, it includes in a direction parallel to a normal, N of the second major surface 114. The emitted blue LED light 125 may also be reflected at an angle, α, with respect to the normal, N of the second major surface 114, wherein 0°<α<90° is fulfilled. At least a portion of the reflected emitted blue LED light 125 is transmitted through the light transmissive carrier 110. As an example, the light scattering material may be configured to reflect 20% to 40% of the emitted blue LED light 125. Hence, a majority of the emitted blue LED light 125 is not reflected by the light scattering material. According to another example, the light scattering material may be configured to reflect 40% to 60% of the emitted blue LED light 125. This example may increase the homogeneity of the light distribution of the emitted LED filament light 105. Therefore, this example may be the most preferable when desiring a homogenous light distribution. According to yet another example, the light scattering material may be configured to reflect 60% to 80% of the emitted blue LED light 125. Hence, a majority of the emitted blue LED light 125 is reflected by the light scattering material. Therefore, the emitted LED filament light 105 according to this example may provide an indirect lighting experience.

The light scattering material may alter the distribution of the emitted blue LED light 125 provided between the first elongated encapsulant 130 and the second elongated encapsulant 140. According to an example, 50% of the emitted blue LED light 125 is provided towards the first elongated encapsulant 130 and 50% of the emitted blue LED light 125 is provided towards the second elongated encapsulant 140. According to the example, the emitted LED filament light 105 may have a CCT below 2800K. Furthermore, the CCT of the emitted LED filament light 105 may also be below 2500K. According to another example, the first luminescent material 132 may comprise (only) a green-yellow phosphor, i.e. not also a red phosphor. Additionally, the example may have 50% of the emitted blue LED light 125 provided towards the first elongated encapsulant 130 and 50% of the emitted blue LED light 125 provided towards the second elongated encapsulant 140. The present example of the LED filament 100 enables a lower CCT of the emitted LED filament light 105 compared to e.g. a LED filament 100 having the first luminescent material 132 also (only) comprising green-yellow phosphor, but instead having 70% of the emitted blue LED light 125 provided towards the first elongated encapsulant 130 and 30% of the emitted blue LED light 125 provided towards the second elongated encapsulant 140. The emitted LED filament light 105 according to the example may have a CCT below 2800K. Furthermore, the CCT of the emitted LED filament light 105 may also be below 2500K.

The LED filament 100 further comprises a fourth encapsulant 160 arranged between the third encapsulant 150 and the first major surface 112 and at least partially covering the first major surface 112 and at least partially enclosing the array of the plurality of first LEDs 120. The fourth encapsulant 160 is transparent. By a “light transmissive encapsulant”, it is here meant an encapsulant which is transparent and/or translucent. The first encapsulant 130 comprises a first thickness, T1, in a direction parallel to a normal, N of the first major surface 112 and the third encapsulant 150 comprises a third thickness, T₃, in a direction parallel to a normal, N of the first major surface 112, wherein T₃>T₁. Furthermore, the fourth encapsulant 160 comprises a fourth thickness, T₄, in a direction parallel to a normal, N of the first major surface 112, wherein T₄>T₃. Therefore, it may follow that T₄>T₃>T₁. It should be noted that the second encapsulant 140 may comprise a second thickness, T₂, in a direction parallel to a normal, N, of the second major surface 114. The first thickness, T₁, of the first encapsulant 130 may be the same or different in relation to the second thickness, T₂, of the second encapsulant 140.

The LED filament 100 may further comprises a fifth encapsulant arranged between the second encapsulant 140 and the second major surface 114 and at least partially covering the second major surface 114. Furthermore, the fifth encapsulant may be light transmissive. By a “light transmissive encapsulant”, it is here meant an encapsulant which is transparent and/or translucent. It should be noted that the fifth encapsulant may comprise a fifth thickness, T₅, in a direction parallel to a normal, N, of the first major surface 112, wherein T₅<T₂. This may result in a decrease of quenching of the second encapsulant 140 comprising the second luminescent material 142. This entails a reduced risk of emission loss from the emitted LED filament light 105.

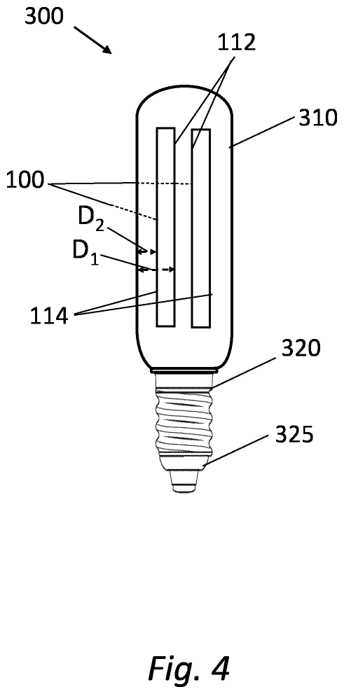

FIG. 4 is a schematic view of a LED filament lamp 300 comprising a first and a second LED filament 100 according to an exemplifying embodiment of the present invention. It should be noted that the LED filaments 100 shown in FIG. 4 has several features in common with the LED filament 100 shown in FIG. 1, and it is hereby referred to FIG. 1 and the associated text for an increased understanding of some of the features and/or functions of the LED filaments 100.

The LED filament lamp 300 further comprises a light transmissive envelope 310 at least partially enclosing the LED filaments 100, and a base 320 wherein the base 320 comprises a cap 325 arranged to mechanically and electrically connect the LED lamp 300 to a socket of a luminaire. In FIG. 4, two LED filament 100 are shown for reasons of simplicity. It should be noted that the quantity of the LED filaments 100 may vary in different embodiments. It should also be noted that the LED filaments 100 may be arranged according to various patterns and/or designs, other than the embodiment shown in FIG. 4.

According to FIG. 4, the first LED filament 100 is arranged such that a first distance, D₁, between the first major surface 112 and the envelope 310, and a second distance, D₂, between the second major surface 114 and the envelope 310, fulfills D₂<D₁. According to FIG. 4, the first major surfaces 112 of the first and the second LED filament 100, with arrays of plurality of first LEDs 120 arranged thereon, are faced towards a midpoint of the envelope 310, respectively. Furthermore, the second major surfaces 114 of the first and second LED filament 100 are faced outwards from the midpoint of the envelope 310, respectively. It should be noted that the arrangement of the LED filaments 100 in relation to the envelope 310 may vary compared to each other.

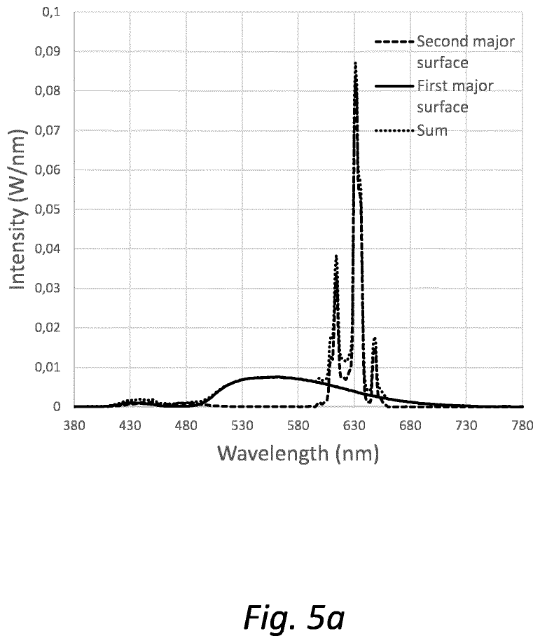

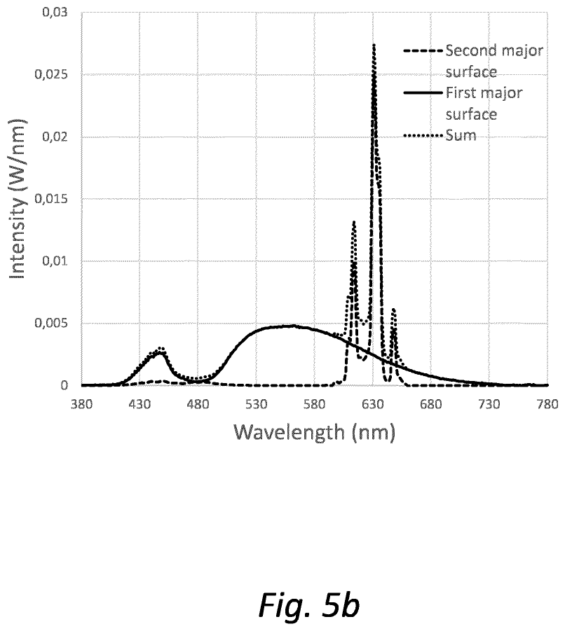

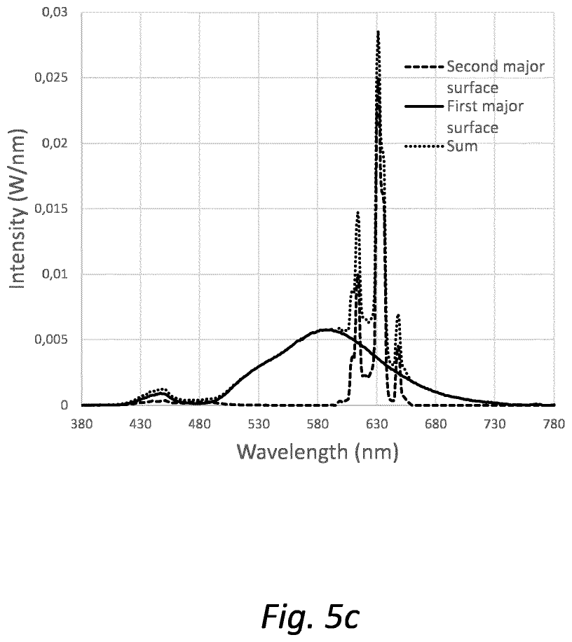

FIGS. 5a to 5c are diagrams illustrating emission intensity against corresponding wavelength of a LED filament 100 according to exemplifying embodiments of the present invention.

FIG. 5a is a diagram describing properties of a LED filament 100, wherein the intensity of the emitted LED filament light 105 is shown on the vertical axis and the wavelength of the emitted LED filament light 105 is shown on the horizontal axis. The dashed line represents emission intensity of emitted light of the second major surface 114. The solid line represents emission intensity of emitted light of the first major surface 112. Finally, the dotted line represents emission intensity of the emitted LED filament light 105. The green-yellow phosphor of first luminescent material 132 comprises YAG (Y₃Al₅O₁₂:Ce3⁺) phosphor and the second luminescent material comprises KSF (K₂SiF₆:Mn⁴⁺) phosphor. FIG. 5a corresponds to an embodiment of the present invention where 50% of the emitted blue LED light 125 is provided towards the first elongated encapsulant 130 and 50% of the emitted blue LED light 125 is provided towards the second elongated encapsulant 140. The embodiment amount in a LED filament 100 having a CCT≥2000K. Furthermore, the embodiment amount in a LED filament 100 having a color rendering index, CRI≥80.

In FIG. 5b, the first luminescent material 132 comprises YAG Y468 phosphor and the second luminescent material 142 comprises KSF phosphor. FIG. 5b corresponds to an embodiment of the present invention where 70% of the emitted blue LED light 125 is provided towards the first elongated encapsulant 130 and 30% of the emitted blue LED light 125 is provided towards the second elongated encapsulant 140. The embodiment amount in a LED filament 100 having a CCT≥2800K. Furthermore, the embodiment amount in a LED filament 100 having a color rendering index, CRI≥90.

In FIG. 5c, the first luminescent material 132 comprises YAG Y468 phosphor and BR2/607a phosphor, and the second luminescent material comprises KSF phosphor. FIG. 5c corresponds to an embodiment of the present invention where 70% of the emitted blue LED light 125 is provided towards the first elongated encapsulant 130 and 30% of the emitted blue LED light 125 is provided towards the second elongated encapsulant 140. The embodiment amount in a LED filament 100 having a CCT≥1500K. Furthermore, the embodiment amount in a LED filament 100 having a CRI≥80. According to an example, the LED filament 100 have a CCT of 2150K and a CRI of 88.

The person skilled in the art realizes that the present invention by no means is limited to the preferred embodiments described above. On the contrary, many modifications and variations are possible within the scope of the appended claims. For example, the LED filament 100, the light transmissive carrier 110, the envelope 310, etc., may have different shapes, dimensions and/or sizes than those depicted/described.

1. A light emitting diode, LED, filament configured to emit LED filament light comprising:
a light transmissive carrier comprising a first major surface, and a second major surface arranged opposite to the first major surface,
an array of a plurality of first LEDs arranged on the first major surface, wherein the plurality of first LEDs is configured to emit blue LED light having a peak emission wavelength within a wavelength range of 430-490 nm,
a first elongated encapsulant at least partially covering the first major surface and at least partially enclosing the array of the plurality of first LEDs, wherein the first encapsulant comprises a first luminescent material configured to at least partly convert the emitted blue LED light into first converted light, wherein the first luminescent material comprises a green-yellow phosphor configured to at least partly convert the emitted blue LED light into second converted light comprising green-yellow light having a peak emission wavelength within a wavelength range of 500-600 nm, and
a second elongated encapsulant at least partially covering the second major surface, comprising a second luminescent material, wherein at least 95 weight percent (w/w %) of the second luminescent material is M′_{z}M_{2-2z}AX₆ doped with tetravalent manganese and wherein the second luminescent material is configured to at least partly convert the emitted blue LED light into fourth converted light comprising red light having a peak emission wavelength within a wavelength range of 600-650 nm;
wherein M′ comprises an alkaline earth cation;
wherein M comprises a cation, and z is in the range from 0 to 1;
wherein A comprises a tetravalent cation;
wherein X comprises at least one monovalent anion, the at least one monovalent anion comprising fluorine;
wherein the luminescent material present in the second elongated encapsulant and comprising the second luminescent material is solely configured to generate light having a peak emission wavelength inside the wavelength range of 600-650 nm; and
wherein the first luminescent material in the first encapsulant has a first concentration, C₁, and the second luminescent material in the second encapsulant has a second concentration, C₂, wherein C₁>1.2·C₂ is fulfilled.

2. The LED filament according to claim 1, wherein the first luminescent material further comprises a red phosphor configured to at least partly convert at least one of the emitted blue LED light and the second converted light into third converted light comprising red light having a peak emission wavelength within a wavelength range of 600-670 nm.

3. The LED filament according to claim 2, wherein the red phosphor comprises M′_{z}M_{2-2z}AX₆ doped with tetravalent manganese;
wherein M′ comprises an alkaline earth cation;
wherein M comprises a cation, and z is in the range from 0 to 1;
wherein A comprises a tetravalent cation;
wherein X comprises at least one monovalent anion, the at least one monovalent anion comprising fluorine; and
wherein the red phosphor is configured to at least partly convert at least one of the emitted blue LED light and the second converted light into third converted light comprising red light having a peak emission wavelength within a wavelength range of 600-650 nm.

4. The LED filament according to claim 1, wherein the first luminescent material further comprises a red nitride phosphor configured to at least partly convert at least one of the emitted blue LED light and the first converted light into fifth converted light comprising red light having an emission peak wavelength within a wavelength range of 640-680 nm, preferably wherein the red nitride phosphor comprises at least one of M₂Si₅N₈:Eu2+, MAlSiN₃:Eu2+, and M₂AlSi₃O₂N₅:Eu2+, wherein M comprises one or more of Ba, Sr and Ca.

5. The LED filament according to claim 1, wherein at least 95 weight percent (w/w %) of the second luminescent material is K₂SiF₆:Mn⁴⁺.

6. The LED filament according to claim 1, wherein the green-yellow phosphor is A₃BsO₁₂:Ce³⁺;
wherein A comprises at least one of Y, La, Gd, Tb and Lu; and
wherein B comprises at least one of Al, Ga, In and Sc.

7. The LED filament according to claim 1, wherein the LED filament light has a correlated color temperature in a range from 1500K to 2800K.

8. The LED filament according to claim 1, wherein the first luminescent material in the first encapsulant has a first concentration, C₁, and the second luminescent material in the second encapsulant has a second concentration, C₂, wherein C₁≥1.2·C₂ is fulfilled.

9. The LED filament according to claim 1, wherein the LED filament comprises
a third encapsulant (150) arranged between the first encapsulant and the first major surface, and at least partially covering the first major surface and at least partially enclosing the array of the plurality of first LEDs, wherein the third encapsulant comprises a light scattering material configured to at least partly reflect the emitted blue LED light through the light transmissive carrier.

10. The LED filament according to claim 9, wherein the light scattering material is configured to reflect 20% to 80% of the emitted blue LED light in a direction facing away from the second major surface, wherein at least a portion of the reflected emitted blue LED light is transmitted through the light transmissive carrier.

11. The LED filament according to claim 9, wherein the first encapsulant comprises a first thickness, T₁, in a direction parallel to a normal, N of the first major surface and the third encapsulant comprises a third thickness, T₃, in a direction parallel to a normal, N of the first major surface, wherein T₃>T₁.

12. The LED filament according to claim 9, wherein the LED filament comprises
a fourth encapsulant arranged between the third encapsulant and the first major surface and at least partially covering the first major surface and at least partially enclosing the array of the plurality of first LEDs, wherein the fourth encapsulant is transparent.

13. The LED filament according to claim 12, wherein the third encapsulant comprises a third thickness, T₃, in a direction parallel to a normal, N of the first major surface, and the fourth encapsulant comprises a fourth thickness, T₄, in a direction parallel to a normal, N of the first major surface, wherein T₄>T₃.

14. A LED filament lamp, comprising:
at least one LED filament according to claim 1,
a light transmissive envelope at least partially enclosing the LED filament, and
a base wherein the base comprises a cap arranged to mechanically and electrically connect the LED lamp to a socket of a luminaire.

15. The LED filament lamp according to claim 14, wherein the LED filament is arranged such that a first distance, D₁, between the first major surface and the envelope, and a second distance, D₂, between the second major surface and the envelope, fulfills D₂<D₁.
